(19) United States
(12) Patent Application Publication
(10) Pub. No.: US 2025/0277834 A1
(43) Pub. Date: Sep. 4, 2025

(54) INSULATION RESISTANCE DETECTION DEVICE AND INSULATION RESISTANCE DETECTION METHOD

(71) Applicant: Panasonic Intellectual Property Management Co., Ltd., Osaka (JP)

(72) Inventors: Tomoaki FURUSE, Osaka (JP); Hideki IWAKI, Osaka (JP)

(73) Assignee: Panasonic Intellectual Property Management Co., Ltd., Osaka (JP)

(21) Appl. No.: 18/860,537

(22) PCT Filed: Apr. 3, 2023
(86) PCT No.: PCT/JP2023/013815

§ 371 Date: Oct. 25, 2024

(30) Foreign Application Priority Data
May 20, 2022 (JP) 2022-083426

(51) Int. Cl. G01R 27/02; G01R 31/52

(52) U.S. Cl. CPC G01R 27/025; G01R 31/52

(57) ABSTRACT

An insulation resistance detection device includes: a voltage measurer that measures a voltage at a first node among a plurality of nodes between a plurality of voltage dividing resistors included in an insulation detection circuit for detecting insulation resistance in a path through which a current from a battery flows; a determiner that determines whether the voltage at the first node measured by the voltage measurer is lower than or equal to a predetermined voltage; and a switcher that switches a state of a switch connected to a second node among the plurality of nodes to cause the voltage measured by the voltage measurer to exceed the predetermined voltage, when the voltage at the first node measured by the voltage measurer is determined to be lower than or equal to the predetermined voltage.

### TECHNICAL FIELD

The present disclosure relates to an insulation resistance detection device and an insulation resistance detection method for detecting insulation resistance in a path through which current from a battery flows.

### BACKGROUND ART

Patent Literature (PTL) 1 describes a device that can detect insulation resistance in a path through which current from a battery flows.

### CITATION LIST

### Patent Literature

[PTL 1] Japanese Unexamined Patent Application Publication No. 2018-128454

### SUMMARY OF INVENTION

### Technical Problem

However, the device described in PTL 1 detects the insulation resistance by measuring the voltage at one node, and if the voltage measured at that node becomes low due to a drop in battery voltage or during the measurement control process, the measurement error of the voltage at that node will increase, and the detection accuracy of the insulation resistance will decrease.

Therefore, the present disclosure provides an insulation resistance detection device and the like that can suppress a decrease in the detection accuracy of insulation resistance even if the voltage of the node at which the voltage is measured decreases.

### Solution to Problem

An insulation resistance detection device according to one embodiment of the present disclosure includes: a voltage measurer that measures a voltage at a first node among a plurality of nodes between a plurality of voltage dividing resistors connected between a positive terminal and a negative terminal of a battery, the plurality of voltage dividing resistors being included in an insulation detection circuit for detecting insulation resistance in a path through which a current from the battery flows; a determiner that determines whether the voltage at the first node measured by the voltage measurer is lower than or equal to a predetermined voltage; and a switcher that switches a state of a switch connected to a second node among the plurality of nodes to cause the voltage measured by the voltage measurer to exceed the predetermined voltage, when the voltage at the first node measured by the voltage measurer is determined to be lower than or equal to the predetermined voltage.

An insulation resistance detection method according to one embodiment of the present disclosure includes: measuring a voltage at a first node among a plurality of nodes between a plurality of voltage dividing resistors connected between a positive terminal and a negative terminal of a battery, the plurality of voltage dividing resistors being included in an insulation detection circuit for detecting insulation resistance in a path through which a current from the battery flows; determining whether the voltage at the first node measured in the measuring is lower than or equal to a predetermined voltage; and switching a state of a switch connected to a second node among the plurality of nodes to cause the voltage measured in the measuring to exceed the predetermined voltage, when the voltage at the first node measured in the measuring is determined to be lower than or equal to the predetermined voltage.

### Advantageous Effects of Invention

According to an insulation resistance detection device according to one embodiment of the present disclosure, a decrease in the detection accuracy of the insulation resistance can be suppressed even if the voltage of the node at which the voltage is measured decreases.

### BRIEF DESCRIPTION OF DRAWINGS

FIG. 1 is a configuration diagram showing an example of an insulation resistance detection device according to Embodiment 1.

FIG. 2 is a diagram for explaining the effect of the insulation resistance detection device according to Embodiment 1.

FIG. 3 is a configuration diagram showing an example of an insulation resistance detection device according to a variation of Embodiment 1.

FIG. 4 is a configuration diagram showing an example of an insulation resistance detection device according to Embodiment 2.

FIG. 5 is a flowchart showing an example of an insulation resistance detection method for another embodiment.

### DESCRIPTION OF EMBODIMENTS

Hereinafter, the embodiments will be described in detail with reference to the drawings.

It should be noted that each of the embodiments described below shows comprehensive or specific examples. The numerical values, shapes, materials, components, arrangement positions and connection forms of the components, and the like shown in the following embodiments are merely examples, and are not intended to limit the present disclosure.

### Embodiment 1

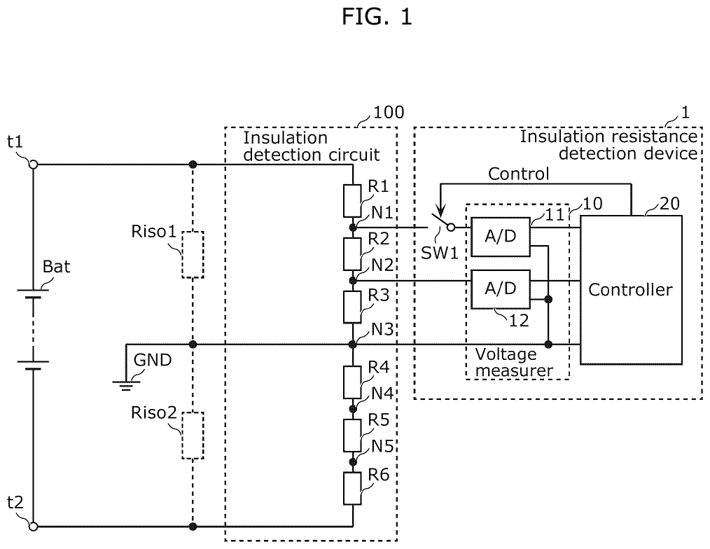

Hereinafter, insulation resistance detection device 1 in Embodiment 1 will be described with reference to FIG. 1.

FIG. 1 is a configuration diagram showing an example of insulation resistance detection device 1 according to Embodiment 1. It should be noted that in addition to insulation resistance detection device 1, FIG. 1 also shows battery Bat, insulation resistance Riso1 and Riso2 in a path through which current from battery Bat flows, and insulation detection circuit 100. It should be noted that battery Bat or insulation detection circuit 100 may be a component of insulation resistance detection device 1.

Insulation resistance detection device 1 is mounted on, for example, a vehicle such as an electric vehicle that uses electric power for propulsion. High-voltage battery Bat is mounted on a vehicle such as an electric vehicle, and power is supplied from battery Bat to a drive load such as a motor to propel the vehicle. Battery Bat is a battery for an HV, PHEV, EV, or the like.

Insulation resistance refers to the insulation between a path through which a current flows and ground, and low insulation resistance can cause leakage current, which can lead to electric shock, fire, and the like. For this reason, detecting insulation resistance can detect dangerous vehicle conditions in advance. FIG. 1 shows insulation resistance Riso1 between the path connected to positive terminal t1 of battery Bat and ground GND, and insulation resistance Riso2 between the path connected to negative terminal t2 of battery Bat and ground GND. Ground GND is, for example, the potential of the vehicle chassis.

Insulation detection circuit 100 is a circuit for detecting insulation resistance Riso1 and Riso2, and includes a plurality of voltage dividing resistors connected between positive terminal t1 and negative terminal t2 of battery Bat. In Embodiment 1, resistors R1, R2, R3, R4, R5, and R6 are shown as the plurality of voltage dividing resistors. Specifically, resistors R1, R2, and R3 are connected in series between positive terminal t1 and ground GND, and resistors R4, R5, and R6 are connected in series between ground GND and negative terminal t2. In this way, positive terminal t1 is connected to ground GND via at least one resistor among the plurality of voltage dividing resistors, and negative terminal t2 is connected to ground GND via at least another resistor among the plurality of voltage dividing resistors. In Embodiment 1, the at least one resistor includes resistors R1, R2, and R3, and the at least another resistor includes resistors R4, R5, and R6. The potential of ground GND can be stabilized by connecting positive terminal t1 to ground GND and ground GND to negative terminal t2 via at least one resistor, respectively.

In addition, nodes N1, N2, N3, N4, and N5 are shown as the plurality of nodes between the plurality of voltage dividing resistors. Node N1 is a node between resistors R1 and R2, node N2 is a node between resistors R2 and R3, node N3 is a node between resistors R3 and R4, node N4 is a node between resistors R4 and R5, and node N5 is a node between resistors R5 and R6.

Although not shown here, insulation detection circuit 100 may include one or more switches connected to one or more of the plurality of voltage divider resistors. By controlling one or more switches included in insulation detection circuit 100, it is possible to change the voltage at any one of the plurality of nodes. Then, insulation resistance detection device 1 can accurately calculate the values of insulation resistance Riso1 and Riso2 from the voltages before and after the change.

It should be noted that insulation detection circuit 100 does not have to include one or more switches as shown in FIG. 1, and even in this case, it is possible to determine whether insulation resistance Riso1 or Riso2 is anomalous (i.e., whether a leakage current has occurred) from the voltage at any one of the plurality of nodes. This is because, if insulation resistance Riso1 or Riso2 is anomalous and its value is low, the voltage at any one of the plurality of nodes will also have an anomalous value.

Insulation resistance detection device 1 is a device for detecting insulation resistance Riso1 and Riso2, and includes voltage measurer 10 and controller 20. Insulation resistance detection device 1 is realized by, for example, a micro controller unit (MCU) or the like. In Embodiment 1, insulation resistance detection device 1 uses the potential of ground GND (node N3) as a reference potential.

Voltage measurer 10 is capable of measuring voltages at a plurality of nodes between a plurality of voltage dividing resistors included in insulation detection circuit 100. For example, voltage measurer 10 includes an A/D converter and measures the voltages at a plurality of nodes using the A/D converter. For example, voltage measurer 10 includes A/D converters 11 and 12 and is capable of measuring the voltage at node N1 using A/D converter 11 and measuring the voltage at node N2 using A/D converter 12. Node N1 is an example of a second node, and node N2 is an example of a first node. In Embodiment 1, voltage measurer 10 measures the voltages at nodes N1 and N2 using the potential of ground GND as a reference.

Controller 20 determines whether the voltage at node N2 measured by voltage measurer 10 is lower than or equal to a predetermined voltage. Controller 20 is an example of a determiner. The predetermined voltage is not particularly limited, and may be, for example, ½, ⅕, or the like of the absolute maximum rating of voltage measurer 10 (A/D converters 11 and 12).

In addition, when the voltage at node N2 measured by voltage measurer 10 is determined to be lower than or equal to a predetermined voltage, controller 20 switches a state of switch SW1 connected to node N1 among the plurality of nodes so that the voltage measured by voltage measurer 10 exceeds the predetermined voltage. Controller 20 is an example of a switcher.

In Embodiment 1, node N1 is a node to which a higher voltage is applied than node N2. Specifically, a voltage corresponding to two resistors R2 and R3 is applied to node N1, and a voltage corresponding to one resistor R3 is applied to node N2, so that a voltage higher than that at node N2 is applied to node N1.

In addition, in Embodiment 1, switch SW1 is connected between node N1 and voltage measurer 10, and when the voltage at node N2 measured by voltage measurer 10 is determined to be lower than or equal to a predetermined voltage, controller 20 switches a state of switch SW1 to connect node N1 and voltage measurer 10. Specifically, in this case, controller 20 switches the state of switch SW1 from a non-conductive state to a conductive state. When the state of switch SW1 is switched to the conductive state, A/D converter 11 of voltage measurer 10 can measure the voltage at node N1.

In addition, controller 20 detects insulation resistance Riso1 and Riso2 based on the voltage measured by voltage measurer 10. For example, when the voltage measured by voltage measurer 10 is an anomalous value, controller 20 can determine that insulation resistance Riso1 or Riso2 is anomalous. For example, when controller 20 controls switch SW1 to a non-conductive state, it detects insulation resistance Riso1 and Riso2 using the voltage at node N2 measured by A/D converter 12, and when controller 20 controls switch SW1 to a conductive state, it detects insulation resistance Riso1 and Riso2 using the voltage at node N1 measured by A/D converter 11.

When insulation detection circuit 100 includes one or more switches, controller 20 can calculate the values of insulation resistance Riso1 and Riso2 using a predetermined algorithm from the voltages at node N1 or N2 measured before and after the states of one or more switches are switched.

It should be noted that voltage measurer 10 may include only one A/D converter, and the A/D converter may measure the voltages at nodes N1 and N2. In this case, a switch is provided between the A/D converter and node N2, and the voltage at node N2 is measured with the switch in a conductive state and switch SW1 in a non-conductive state. When the voltage at node N2 is determined to be lower than or equal to a predetermined voltage, the switch is made in a non-conductive state and switch SW1 is made in a conductive state, and the voltage at node N1 is measured.

In addition, controller 20 may diagnose a fault in insulation detection circuit 100 or voltage measurer 10 by comparing the voltage at node N2 with the voltage at node N1 which are measured by voltage measurer 10. Controller 20 is an example of a fault diagnoser. For example, the ratio between the voltage at node N1 and the voltage at node N2 should be a constant ratio according to the resistance values of resistors R1, R2, and R3, but if the constant ratio is not achieved, it can be determined that at least one of resistor R1, R2, or R3 is faulty, or that voltage measurer 10 is faulty.

In addition, four or more voltage dividing resistors may be connected between positive terminal t1 and ground GND, and for example, when the voltage at node N1 also falls below a predetermined voltage, a node to which a voltage higher than node N1 is applied may be connected by a switch to voltage measurer 10, and the voltage at that node may be measured. Then, when the voltage at that node also falls below the predetermined voltage, the voltage at another node to which a higher voltage is applied may be measured.

In addition, although not shown, voltage measurer 10 may measure the voltage at node N4 or N5, and controller 20 may detect insulation resistance Riso1 and Riso2 using the voltage at node N4 or N5 as well. Alternatively, the plurality of voltage dividing resistors may not be connected between ground GND and negative terminal t2 as shown in FIG. 1, and for example, only one resistor may be connected therebetween. In this case, voltage measurer 10 may not measure the voltage of the node between ground GND and negative terminal t2.

As described above, insulation resistance detection device 1 includes: voltage measurer 10 that measures a voltage at node N2 among a plurality of nodes between a plurality of voltage dividing resistors connected between positive terminal t1 and negative terminal t2 of battery Bat, the plurality of voltage dividing resistors being included in insulation detection circuit 100 for detecting insulation resistance Riso1 and Riso 2 in a path through which a current from battery Bat flows; a determiner (controller 20) that determines whether the voltage at node N2 measured by voltage measurer 10 is lower than or equal to a predetermined voltage; and a switcher (controller 20) that switches a state of switch SW1 connected to node N1 among the plurality of nodes to cause the voltage measured by voltage measurer 10 to exceed the predetermined voltage, when the voltage at node N2 measured by voltage measurer 10 is determined to be lower than or equal to the predetermined voltage.

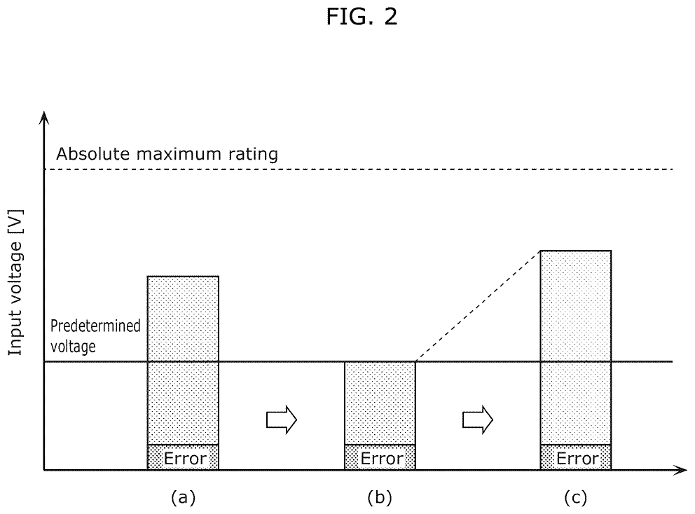

According to this, when the voltage measured at node N2 falls below a predetermined voltage due to a voltage drop in battery Bat or during a measurement control process, the state of switch SW1 is switched so that the voltage measured by voltage measurer 10 exceeds the predetermined voltage. Therefore, voltage measurer 10 can measure a voltage higher than the predetermined voltage, and the measurement error of voltage measurer 10 can be reduced. Therefore, even if the voltage at node N2, where the voltage is measured, drops, a decrease in the detection accuracy of insulation resistance Riso1 and Riso2 can be suppressed. This will be explained in detail with reference to FIG. 2.

FIG. 2 is a diagram for explaining the effects of insulation resistance detection device 1 according to Embodiment 1.

As shown in (a) in FIG. 2, when the voltage measured by voltage measurer 10 (the voltage at node N2 in Embodiment 1) exceeds a predetermined voltage, switch SW1 is made in a non-conductive state. Thereafter, the voltage of battery Bat drops, and as shown in (b) in FIG. 2, it is assumed that the voltage measured by voltage measurer 10 (the voltage at node N2 in Embodiment 1) falls below the predetermined voltage. In this case, the ratio of error to the input voltage to voltage measurer 10 (A/D converter 11) increases, and the measurement error of voltage measurer 10 increases. Therefore, the state of switch SW1 connected between node N1 and voltage measurer 10 is switched from a non-conductive state to a conductive state, and voltage measurer 10 measures the voltage at node N1. As shown in (c) in FIG. 2, since the voltage at node N1 is higher than the voltage at node N2, the ratio of error to the input voltage to voltage measurer 10 (A/D converter 12) can be reduced, and the measurement error of voltage measurer 10 can be reduced.

It should be noted that voltage measurer 10 does not measure the voltage at node N1 before the voltage of battery Bat drops, in other words, before the voltage at node N2 falls below a predetermined voltage, because there is a risk that the voltage at node N1 will exceed the absolute maximum rating of voltage measurer 10.

For example, node N1 is a node to which a higher voltage is applied than node N2, switch SW1 is connected between node N1 and voltage measurer 10, and when the voltage at node N2 measured by voltage measurer 10 is determined to be lower than or equal to a predetermined voltage, the switcher (controller 20) switches a state of switch SW1 to connect node N1 and voltage measurer 10, and voltage measurer 10 may measure the voltage at node N1.

According to this, when the voltage measured at node N2 falls below a predetermined voltage due to a voltage drop in battery Bat or during a measurement control process, node N1, to which a voltage higher than that of node N2 is applied, is connected to voltage measurer 10 by switch SW1. Therefore, voltage measurer 10 can measure a voltage higher than the predetermined voltage at node N1, and the measurement error of voltage measurer 10 can be reduced. In this way, by switching the node at which voltage measurer 10 measures the voltage to a node to which a higher voltage is applied when the voltage of battery Bat drops or the like, a decrease in the detection accuracy of insulation resistance Riso1 and Riso2 can be suppressed.

For example, voltage measurer 10 may measure the voltages at nodes N1 and N2 using the potential of ground GND as a reference.

For example, insulation resistance detection device 1 is realized by a micro controller unit or the like, and in Embodiment 1, when the reference potential of the micro controller unit is set to the potential of ground GND, the voltages at nodes N1 and N2 can also be measured with ground GND potential as a reference.

For example, insulation resistance detection device 1 may further include a fault diagnoser (controller 20) that diagnoses a fault in insulation detection circuit 100 or voltage measurer 10 by comparing the voltage at node N2 with the voltage at node N1 which are measured by voltage measurer 10.

This makes it possible to diagnose a fault in insulation detection circuit 100 or voltage measurer 10 depending on whether the ratio of the voltage at node N1 to the voltage at node N2 is constant.

### (Variation of Embodiment 1)

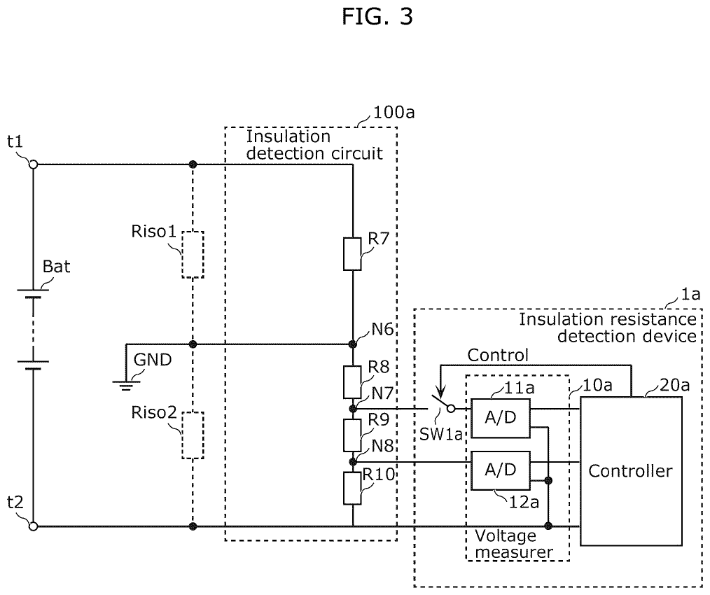

Next, insulation resistance detection device 1a according to a variation of Embodiment 1 will be described with reference to FIG. 3. Hereinafter, differences from insulation resistance detection device 1 according to Embodiment 1 will be mainly described, and descriptions of the same points will be omitted.

FIG. 3 is a configuration diagram showing an example of insulation resistance detection device 1a according to a variation of Embodiment 1. It should be noted that in addition to insulation resistance detection device 1a, FIG. 3 also shows battery Bat, insulation resistance Riso1 and Riso2 in a path through which current flows from battery Bat, and insulation detection circuit 100a. It should be noted that battery Bat or insulation detection circuit 100a may be a component of insulation resistance detection device 1a.

Insulation resistance detection device 1a is mounted on, for example, a vehicle, such as an electric vehicle, that uses electricity for propulsion.

Insulation detection circuit 100a is a circuit for detecting insulation resistance Riso1 and Riso2, and includes a plurality of voltage dividing resistors connected between positive terminal t1 and negative terminal t2 of battery Bat. In the variation of Embodiment 1, resistors R7, R8, R9, and R10 are shown as the plurality of voltage dividing resistors. Specifically, resistor R7 is connected between positive terminal t1 and ground GND, and resistors R8, R9, and R10 are connected in series between ground GND and negative terminal t2. In this manner, positive terminal t1 is connected to ground GND via at least one resistor among the plurality of voltage dividing resistors, and negative terminal t2 is connected to ground GND via at least another resistor among the plurality of voltage dividing resistors. In the variation of Embodiment 1, the at least one resistor is resistor R7, and the at least another resistor includes resistors R8, R9, and R10. The potential of ground GND can be stabilized by connecting positive terminal t1 to ground GND and ground GND to negative terminal t2 via at least one resistor, respectively.

In addition, nodes N6, N7, and N8 are shown as a plurality of nodes between the voltage dividing resistors. Node N6 is a node between resistors R7 and R8, node N7 is a node between resistors R8 and R9, and node N8 is a node between resistors R9 and R10.

Although not shown here, insulation detection circuit 100a may include one or more switches connected to one or more of the plurality of voltage divider resistors. By controlling one or more switches included in insulation detection circuit 100a, the voltage at any one of the plurality of nodes can be changed. Then, insulation resistance detection device 1a can accurately calculate the values of insulation resistance Riso1 and Riso2 from the voltages before and after the change.

It should be noted that insulation detection circuit 100a may not include one or more switches as shown in FIG. 3, and even in this case, it is possible to determine whether insulation resistance Riso1 or Riso2 is anomalous (i.e., whether a leakage current has occurred) from the voltage at any one of the plurality of nodes.

Insulation resistance detection device 1a is a device for detecting insulation resistance Riso1 and Riso2, and includes voltage measurer 10a and controller 20a. Insulation resistance detection device 1a is realized by, for example, a micro controller unit or the like. In the variation of Embodiment 1, insulation resistance detection device 1a uses the potential of negative terminal t2 as a reference potential.

Voltage measurer 10a can measure voltages at a plurality of nodes between a plurality of voltage dividing resistors included in insulation detection circuit 100a. For example, voltage measurer 10a includes an A/D converter and measures voltages at the plurality of nodes by the A/D converter. For example, voltage measurer 10a includes A/D converters 11a and 12a and can measure the voltage at node N7 by A/D converter 11a and can measure the voltage at node N8 by A/D converter 12a. Node N7 is an example of a second node, and node N8 is an example of a first node. In the variation of Embodiment 1, voltage measurer 10a measures the voltages at nodes N7 and N8 using the potential of negative terminal t2 as a reference.

Controller 20a determines whether the voltage at node N8 measured by voltage measurer 10a is lower than or equal to a predetermined voltage. Controller 20a is an example of a determiner. The predetermined voltage is not particularly limited, but may be, for example, ½, ⅕, or the like of the absolute maximum rating of voltage measurer 10a (A/D converters 11a and 12a).

In addition, when controller 20a determines that the voltage at node N8 measured by voltage measurer 10a is lower than or equal to a predetermined voltage, controller 20a switches a state of switch SW1a connected to node N7 among the plurality of nodes so that the voltage measured by voltage measurer 10a exceeds the predetermined voltage. Controller 20a is an example of a switcher. Node N7 is an example of a second node.

In the variation of Embodiment 1, node N7 is a node to which a higher voltage than that of node N8 is applied. Specifically, a voltage corresponding to two resistors R9 and R10 is applied to node N7, and a voltage corresponding to single resistor R10 is applied to node N8, so that a voltage higher than that of node N8 is applied to node N7.

In addition, in the variation of Embodiment 1, switch SW1a is connected between node N7 and voltage measurer 10a, and when the voltage at node N8 measured by voltage measurer 10a is determined to be lower than or equal to a predetermined voltage, controller 20a switches a state of switch SW1a to connect node N7 and voltage measurer 10a. Specifically, in this case, controller 20a switches the state of switch SW1a from a non-conductive state to a conductive state. When the state of switch SW1a is switched to the conductive state, A/D converter 11a of voltage measurer 10a can measure the voltage at node N7.

In addition, controller 20a detects insulation resistance Riso1 and Riso2 based on the voltage measured by voltage measurer 10a. For example, when the voltage measured by voltage measurer 10a is an anomalous value, controller 20a can determine that insulation resistance Riso1 or Riso2 is anomalous. For example, when controller 20a controls switch SW1a to a non-conductive state, it detects insulation resistance Riso1 and Riso2 using the voltage at node N8 measured by A/D converter 12a, and when controller 20a controls switch SW1a to a conductive state, it detects insulation resistance Riso1 and Riso2 using the voltage at node N7 measured by A/D converter 11a.

When insulation detection circuit 100a includes one or more switches, controller 20a can calculate the values of insulation resistance Riso1 and Riso2 using a predetermined algorithm from the voltages at node N7 or N8 measured before and after the states of one or more switches are switched.

It should be noted that voltage measurer 10a may include only one A/D converter, and the A/D converter may measure the voltages at nodes N7 and N8. In this case, a switch is also provided between the A/D converter and node N8, and the voltage at node N8 is measured with the switch in a conductive state and switch SW1a in a non-conductive state. When the voltage at node N8 is determined to be lower than or equal to a predetermined voltage, the switch is made in a non-conductive state and switch SW1a is made in a conductive state, and the voltage at node N7 is measured.

In addition, controller 20a may diagnose a fault in insulation detection circuit 100a or voltage measurer 10a by comparing the voltage at node N8 with the voltage at node N7 which are measured by voltage measurer 10a. Controller 20a is an example of a fault diagnoser. For example, the ratio between the voltage at node N7 and the voltage at node N8 should be a constant ratio according to the resistance values of resistors R8, R9, and R10, but if the constant ratio is not achieved, it can be determined that at least one of resistor R8, R9, or R10 is faulty, or that voltage measurer 10a is faulty.

In addition, four or more voltage dividing resistors may be connected between ground GND and negative terminal t2, and for example, when the voltage at node N7 also falls below a predetermined voltage, a node to which a voltage higher than that of node N7 is applied may be connected by a switch to voltage measurer 10a, and the voltage at that node may be measured. Then, when the voltage at that node also falls below the predetermined voltage, the voltage at another node to which a higher voltage is applied may be measured.

As described above, in the variation of Embodiment 1, voltage measurer 10a may measure the voltages at nodes N7 and N8 using the potential of negative terminal t2 as a reference.

For example, insulation resistance detection device 1a is realized by a micro controller unit or the like, and in the variation of Embodiment 1, when the reference potential of the micro controller unit is set to the potential of negative terminal t2, the voltages at nodes N7 and N8 can also be measured using the potential of negative terminal t2 as a reference.

It should be noted that in the variation of Embodiment 1, as in Embodiment 1, even if the voltage of node N8 drops due to a voltage drop in battery Bat or during a measurement control process, a decrease in the detection accuracy of insulation resistance Riso1 and Riso2 can be suppressed.

### Embodiment 2

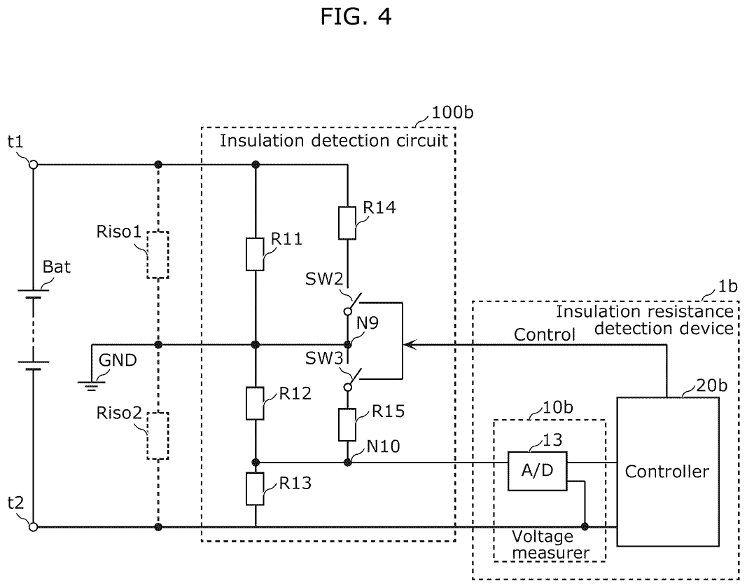

Next, insulation resistance detection device 1b according to Embodiment 2 will be described with reference to FIG. 4. Hereinafter, differences from insulation resistance detection device 1 according to Embodiment 1 will be mainly described, and descriptions of the same points will be omitted.

FIG. 4 is a configuration diagram showing an example of insulation resistance detection device 1b according to Embodiment 2. It should be noted that in addition to insulation resistance detection device 1b, FIG. 4 also shows battery Bat, insulation resistance Riso1 and Riso2 in a path through which current flows from battery Bat, and insulation detection circuit 100b. It should be noted that battery Bat or insulation detection circuit 100b may be a component of insulation resistance detection device 1b.

Insulation resistance detection device 1b is mounted on a vehicle, such as an electric vehicle, that uses electricity for propulsion.

Insulation detection circuit 100b is a circuit for detecting insulation resistance Riso1 and Riso2, and includes a plurality of voltage dividing resistors connected between positive terminal t1 and negative terminal t2 of battery Bat. In Embodiment 2, resistors R11, R12, R13, R14, and R15 are shown as the plurality of voltage dividing resistors. Specifically, resistors R11 and R14 are connected in parallel between positive terminal t1 and ground GND, and a circuit in which resistors R12 and R15 are connected in parallel and resistor R13 are connected in series between ground GND and negative terminal t2. In this way, positive terminal t1 is connected to ground GND via at least one resistor among the plurality of voltage dividing resistors, and negative terminal t2 is connected to ground GND via at least another resistor among the plurality of voltage dividing resistors. In Embodiment 2, the at least one resistor includes resistors R11 and R14, and the at least another resistor includes resistors R12, R13, and R15. The potential of ground GND can be stabilized by connecting positive terminal t1 to ground GND, and ground GND to negative terminal t2 via one or more resistors, respectively.

In addition, nodes N9 and N10 are shown as a plurality of nodes between the voltage dividing resistors. Node N9 is a node between the parallel circuit of resistors R11 and R14 and the parallel circuit of resistors R12 and R15, and node N10 is a node between the parallel circuit of resistors R12 and R15 and resistor R13.

Insulation detection circuit 100b includes switches SW2 and SW3. Switches SW2 and SW3 are connected to node N9 and one of the plurality of voltage dividing resistors. Here, switch SW2 is connected between node N9 and resistor R14, and switch SW3 is connected between node N9 and resistor R15. Node N9 is an example of a second node. When switch SW2 is in a conductive state, the resistance value of the parallel circuit of resistors R11 and R14 is small, and when switch SW2 is in a non-conductive state, the resistance value of the parallel circuit of resistors R11 and R14 is large. When switch SW3 is in a conductive state, the resistance value of the parallel circuit of resistors R12 and R15 is small, and when switch SW3 is in a non-conductive state, the resistance value of the parallel circuit of resistors R12 and R15 is large.

Although not shown here, in addition to switches SW2 and SW3, insulation detection circuit 100b may further include one or more switches connected to one or more voltage dividing resistors among resistors R11, R12, and R13. The voltage at node N10 can be changed by controlling the one or more switches further included in insulation detection circuit 100b. Then, the values of insulation resistance Riso1 and Riso2 can be accurately calculated by insulation resistance detection device 1b from the voltages before and after the change.

It should be noted that as shown in FIG. 4, insulation detection circuit 100b may not include any switches other than switches SW2 and SW3, and even in this case, it is possible to determine from the voltage at node N10 whether insulation resistance Riso1 or Riso2 is anomalous (i.e., whether a leakage current has occurred).

Insulation resistance detection device 1b is a device for detecting insulation resistance Riso1 and Riso2, and includes voltage measurer 10b and controller 20b. Insulation resistance detection device 1b is realized by, for example, a micro controller unit. In Embodiment 2, insulation resistance detection device 1b uses the potential of negative terminal t2 as a reference potential.

Voltage measurer 10b measures the voltage at node N10 among a plurality of nodes between a plurality of voltage dividing resistors included in insulation detection circuit 100b. For example, voltage measurer 10b includes A/D converter 13, and measures the voltage at node N10 using A/D converter 13. Node N10 is an example of a first node. In Embodiment 2, voltage measurer 10b measures the voltage at node N10 using the potential of negative terminal t2 as a reference.

Controller 20b determines whether the voltage at node N10 measured by voltage measurer 10b is lower than or equal to a predetermined voltage. Controller 20b is an example of a determiner. The predetermined voltage is not particularly limited, but may be, for example, ½, ⅕, or the like of the absolute maximum rating of voltage measurer 10b (A/D converter 13).

In addition, when the voltage at node N10 measured by voltage measurer 10b is determined to be lower than or equal to a predetermined voltage, controller 20b switches states of switches SW2 and SW3 connected to node N9 so that the voltage at node N10 measured by voltage measurer 10b exceeds the predetermined voltage. Controller 20b is an example of a switcher.

For example, when switches SW2 and SW3 are in a non-conductive state and the voltage at node N10 is lower than or equal to a predetermined voltage, controller 20b switches a state of at least one of switch SW2 or SW3 to a conductive state. This allows the voltage at node N10 to be increased, and the voltage at node N10 can exceed the predetermined voltage.

In Embodiment 1, an example was described in which the node at which voltage measurer 10 measures the voltage is switched by controlling switch SW1, but in Embodiment 2, the voltage applied to the node at which voltage measurer 10b measures the voltage is switched by controlling switches SW2 and SW3.

In addition, controller 20b detects insulation resistance Riso1 and Riso2 based on the voltage measured by voltage measurer 10b. For example, when the voltage measured by voltage measurer 10b is an anomalous value, controller 20b can determine that insulation resistance Riso1 or Riso2 is anomalous.

It should be noted that when insulation detection circuit 100b includes one or more switches in addition to switches SW2 and SW3, controller 20b can calculate the values of insulation resistance Riso1 and Riso2 using a predetermined algorithm from the voltages at node N10 measured before and after the states of one or more switches are switched.

In addition, controller 20b may diagnose a fault in insulation detection circuit 100b or voltage measurer 10b by comparing the voltages at node N10 measured by voltage measurer 10b before and after the states of switches SW2 and SW3 are switched. Controller 20b is an example of a fault diagnoser. For example, the ratio between the voltages at node N10 before and after the states of switches SW2 and SW3 are switched should be a constant ratio according to the resistance values of resistors R11, R12, R13, R14, and R15, but if the constant ratio is not achieved, it can be determined that at least one of resistor R11, R12, R13, R14, or R15 is faulty, or that voltage measurer 10b is faulty.

In addition, the switch connected to node N9 includes two switches SW2 and SW3 has been described in Embodiment 2, but the present invention is not limited thereto. For example, the switch connected to node N9 may be one, or three or more.

In addition, an example in which voltage measurer 10b measures the voltage at node N10 using the potential of negative terminal t2 as a reference has been described in Embodiment 2, but voltage measurer 10b may also measure the voltage at node N10 using the potential of ground GND as a reference.

The effects of insulation resistance detection device 1b according to Embodiment 2 can also be explained with reference to FIG. 2, in the same manner as Embodiment 1.

As shown in (a) in FIG. 2, when the voltage measured by voltage measurer 10b (the voltage at node N10 in Embodiment 2) exceeds a predetermined voltage, switches SW2 and SW3 are made in a non-conductive state. Thereafter, the voltage of battery Bat drops, and as shown in (b) in FIG. 2, it is assumed that the voltage measured by voltage measurer 10b (the voltage at node N10 in Embodiment 2) falls below the predetermined voltage. In this case, the ratio of error to the input voltage to voltage measurer 10b (A/D converter 13) increases, and the measurement error of voltage measurer 10b increases. Therefore, the states of switches SW2 and SW3 are switched from a non-conductive state to a conductive state, and voltage measurer 10b measures the voltage at node N10. As shown in (c) in FIG. 2, since the voltage at node N10 is higher than the voltage before the states of switches SW2 and SW3 are switched, the ratio of error to the input voltage to voltage measurer 10b (A/D converter 13) can be reduced, and the measurement error of voltage measurer 10b can be reduced.

It should be noted that also in Embodiment 2, as in Embodiment 1, a switch may be connected between a node to which a voltage higher than node N10 is applied and voltage measurer 10b, and when the voltage at node N10 is determined to be lower than or equal to a predetermined voltage, the state of the switch may be switched to measure the voltage at the node to which a voltage higher than node N10 is applied. This can improve the detection accuracy of insulation resistance Riso1 and Riso2.

As described above, in Embodiment 2, switches SW2 and SW3 are connected to node N9 and any one of a plurality of voltage dividing resistors, and when the voltage at node N10 measured by voltage measurer 10b is determined to be lower than or equal to a predetermined voltage, the switcher (controller 20b) switches the states of switches SW2 and SW3 so that the voltage at node N10 measured by voltage measurer 10b exceeds the predetermined voltage.

According to this, when the voltage measured at node N10 falls below a predetermined voltage due to a voltage drop in battery Bat or during a measurement control process, the states of switches SW2 and SW3 are switched so that the voltage applied to node N10 becomes higher. Therefore, voltage measurer 10b can measure a voltage higher than the predetermined voltage at node N10, and the measurement error of voltage measurer 10b can be reduced. In this way, by switching the voltage applied to node N10 at which voltage measurer 10b measures the voltage when the voltage of battery Bat drops or the like, a decrease in the detection accuracy of insulation resistance Riso1 and Riso2 can be suppressed.

For example, voltage measurer 10b may measure the voltage at node N10 using the potential of ground GND as a reference.

For example, insulation resistance detection device 1b is realized by a micro controller unit or the like, and in Embodiment 2, when the reference potential of the micro controller unit is set to ground GND potential, the voltage at node N10 can also be measured using the potential of ground GND as a reference.

Alternatively, for example, voltage measurer 10b may measure the voltage at node N10 using the potential of negative terminal t2 as a reference.

For example, insulation resistance detection device 1b is realized by a micro controller unit or the like, and in Embodiment 2, when the reference potential of the micro controller unit is set to the potential of negative terminal t2, the voltage at node N10 can also be measured using the potential of negative terminal t2 as a reference.

For example, insulation resistance detection device 1b may further include a fault diagnoser (controller 20b) that diagnoses a fault in insulation detection circuit 100b or voltage measurer 10b by comparing the voltages at node N10 measured by voltage measurer 10b before and after the states of switches SW2 and SW3 are switched.

This makes it possible to diagnose a fault in insulation detection circuit 100b or voltage measurer 10b depending on whether the ratio of the voltages at node N10 before and after the states of switches SW2 and SW3 are switched is constant.

### OTHER EMBODIMENTS

As described above, the embodiments have been described as examples of the technology according to the present disclosure. However, the technology according to the present disclosure is not limited thereto, and can be applied to embodiments in which modifications, substitutions, additions, omissions, or the like are made as appropriate. For example, the following variations are also included in one embodiment of the present disclosure.

For example, the present disclosure can be realized not only as an insulation resistance detection device, but also as an insulation resistance detection method that includes steps (processing) performed by components included in the insulation resistance detection device.

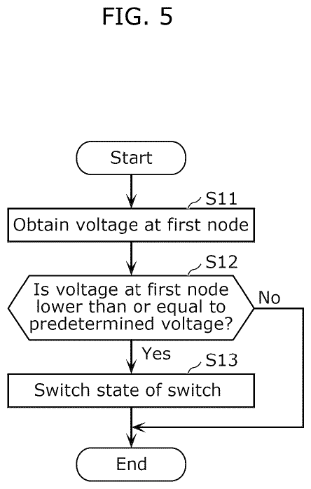

FIG. 5 is a flowchart showing an example of an insulation resistance detection method according to another embodiment.

As shown in FIG. 5, the insulation resistance detection method includes: a voltage measuring step (step S11) of measuring a voltage at a first node among a plurality of nodes between a plurality of voltage dividing resistors connected between a positive terminal and a negative terminal of a battery, the plurality of voltage dividing resistors being included in an insulation detection circuit for detecting insulation resistance in a path through which a current from the battery flows; a determining step (step S12) of determining whether the voltage at the first node measured in the measuring is lower than or equal to a predetermined voltage; and a switching step (step S13) of switching a state of a switch connected to a second node among the plurality of nodes to cause the voltage measured in the measuring to exceed the predetermined voltage, when the voltage at the first node measured in the measuring is determined to be lower than or equal to the predetermined voltage (Yes in step S12).

For example, the steps in the insulation resistance detection method may be executed by a computer (computer system). The present disclosure can be realized as a program for causing a computer to execute the steps included in the insulation resistance detection method.

Furthermore, the present disclosure can be realized as a non-transitory computer-readable recording medium such as a CD-ROM having recorded the program thereon.

For example, when the present invention is realized as a program (software), each step is executed by running the program using hardware resources such as a computer's CPU, memory, input/output circuits, and the like. That is, each step is executed by the CPU obtaining data from memory, input/output circuits, or the like to perform calculations, or outputting the results of the calculations to memory, input/output circuits, or the like.

In addition, each component included in the insulation resistance detection devices of the above embodiments may be realized as a dedicated or general-purpose circuit.

In addition, each component included in the insulation resistance detection devices of the above embodiments may be realized as a large scale integration (LSI), which is an integrated circuit (IC).

In addition, the integrated circuit is not limited to an LSI, and may be realized by a dedicated circuit or a general-purpose processor. A programmable field programmable gate array (FPGA) or a reconfigurable processor in which the connections and settings of circuit cells within the LSI can be reconfigured may be used.

Furthermore, if an integrated circuit technology that replaces an LSI appears due to advances in semiconductor technology or another technology derived therefrom, that technology may naturally be used to integrate the components included in the insulation resistance detection device.

In addition, forms obtained by applying various modifications to each embodiment conceived by a person skilled in the art or forms realized by arbitrarily combining the components and functions in each embodiment without departing from the spirit of the present disclosure are also included in this disclosure.

### INDUSTRIAL APPLICABILITY

The present disclosure can be applied to a device that detects insulation resistance in a path through which current flows from a high-voltage battery mounted in a vehicle or the like.

### REFERENCE SIGNS LIST

1, 1a, 1b Insulation resistance detection device
10, 10a, 10b Voltage measurer
11, 11a, 12, 12a, 13 A/D converter
20, 20a, 20b Controller
100, 100a, 100b Insulation detection circuit
Bat Battery
GND Ground
N1, N2, N3, N4, N5, N6, N7, N8, N9, N10 Node
R1, R2, R3, R4, R5, R6, R7, R8, R9, R10, R11, R12, R13, R14, R15 Resistance
Riso1, Riso2 Insulation resistance
SW1, SW1a, SW2, SW3 Switch
t1 Positive terminal
t2 Negative terminal

1. An insulation resistance detection device comprising:
a voltage measurer that measures a voltage at a first node among a plurality of nodes between a plurality of voltage dividing resistors connected between a positive terminal and a negative terminal of a battery, the plurality of voltage dividing resistors being included in an insulation detection circuit for detecting insulation resistance in a path through which a current from the battery flows;
a determiner that determines whether the voltage at the first node measured by the voltage measurer is lower than or equal to a predetermined voltage; and
a switcher that switches a state of a switch connected to a second node among the plurality of nodes to cause the voltage measured by the voltage measurer to exceed the predetermined voltage, when the voltage at the first node measured by the voltage measurer is determined to be lower than or equal to the predetermined voltage.

2. The insulation resistance detection device according to claim 1,
wherein the second node is a node to which a voltage higher than the voltage at the first node is applied,
the switch is connected between the second node and the voltage measurer,
the switcher switches the state of the switch to connect the second node and the voltage measurer, when the voltage at the first node measured by the voltage measurer is determined to be lower than or equal to the predetermined voltage, and
the voltage measurer measures a voltage at the second node.

3. The insulation resistance detection device according to claim 2,
wherein the positive terminal is connected to ground via at least one of the plurality of voltage dividing resistors,
the negative terminal is connected to the ground via at least an other one of the plurality of voltage dividing resistors, and
the voltage measurer measures the voltage at the first node and the voltage at the second node using a potential of the ground as a reference.

4. The insulation resistance detection device according to claim 2,
wherein the voltage measurer measures the voltage at the first node and the voltage at the second node using a potential of the negative terminal as a reference.

5. The insulation resistance detection device according to claim 2, further comprising:
a fault diagnoser that diagnoses a fault in the insulation detection circuit or the voltage measurer by comparing the voltage at the first node with the voltage at the second node which are measured by the voltage measurer.

6. The insulation resistance detection device according to claim 1,
wherein the switch is connected to the second node and any one of the plurality of voltage dividing resistors, and
the switcher switches the state of the switch to cause the voltage at the first node measured by the voltage measurer to exceed the predetermined voltage, when the voltage at the first node measured by the voltage measurer is determined to be lower than or equal to the predetermined voltage.

7. The insulation resistance detection device according to claim 6,
wherein the positive terminal is connected to ground via at least one of the plurality of voltage dividing resistors,
the negative terminal is connected to the ground via at least an other one of the plurality of voltage dividing resistors, and
the voltage measurer measures the voltage at the first node using a potential of the ground as a reference.

8. The insulation resistance detection device according to claim 6,
wherein the voltage measurer measures the voltage at the first node using a potential of the negative terminal as a reference.

9. The insulation resistance detection device according to claim 6, further comprising:
a fault diagnoser that diagnoses a fault in the insulation detection circuit or the voltage measurer by comparing the voltage at the first node measured by the voltage measurer before the state of the switch is switched and the voltage at the first node measured by the voltage measurer after the state of the switch is switched.

10. An insulation resistance detection method comprising:
measuring a voltage at a first node among a plurality of nodes between a plurality of voltage dividing resistors connected between a positive terminal and a negative terminal of a battery, the plurality of voltage dividing resistors being included in an insulation detection circuit for detecting insulation resistance in a path through which a current from the battery flows;
determining whether the voltage at the first node measured in the measuring is lower than or equal to a predetermined voltage; and
switching a state of a switch connected to a second node among the plurality of nodes to cause the voltage measured in the measuring to exceed the predetermined voltage, when the voltage at the first node measured in the measuring is determined to be lower than or equal to the predetermined voltage.
